(19) United States
(12) Patent Application Publication
(10) Pub. No.: US 2026/0128729 A1
(43) Pub. Date: May 7, 2026

(54) ACOUSTIC WAVE DEVICE

(71) Applicant: Murata Manufacturing Co., Ltd., Nagaokakyo-shi (JP)

(72) Inventors: Masaaki MATSUMORI, Nagaokakyo-shi (JP); Kentaro FUJINAGA, Nagaokakyo-shi (JP)

(21) Appl. No.: 19/437,422

(22) Filed: Dec. 31, 2025

Related U.S. Application Data
(63) Continuation of application No. PCT/JP2024/027431, filed on Jul. 31, 2024.

(30) Foreign Application Priority Data
Aug. 9, 2023 (JP) 2023-129696

(51) Int. Cl. H03H 9/25; H03H 9/02

(52) U.S. Cl. CPC H03H 9/25; H03H 9/02086; H03H 9/02818; H03H 9/02992

(57) ABSTRACT

An acoustic wave device includes a first substrate including first and second main surfaces, a second substrate including a third main surface, a functional electrode on the third main surface, a support portion between the first and third main surfaces to provide a space therebetween, and via conductors in the first substrate and extending from the first main surface toward the second main surface. The support portion includes first and second metal films in contact with each other. In plan view of the first main surface, a region of the first metal film includes a region of the second metal film and an area of the first metal film is larger than an area of the second metal film, and a hardness of the second metal film is greater than a hardness of the first metal film.

### CROSS REFERENCE TO RELATED APPLICATIONS

This application claims the benefit of priority to Japanese Patent Application No. 2023-129696 filed on Aug. 9, 2023 and is a Continuation application of PCT Application No. PCT/JP2024/027431 filed on Jul. 31, 2024. The entire contents of each application are hereby incorporated herein by reference.

### BACKGROUND OF THE INVENTION

### 1. Field of the Invention

The present invention relates to acoustic wave devices.

### 2. Description of the Related Art

Japanese Unexamined Patent Application Publication No. 2018-137742 discloses an electronic device including a piezoelectric thin-film resonating unit, a first substrate (piezoelectricity substrate) on which the piezoelectric thin-film resonating unit is disposed, a second substrate (lid substrate) sandwiching the piezoelectric thin-film resonating unit between the first substrate and the second substrate, a thin film of a high resistivity material formed on the second substrate, and a via conductor provided in the first substrate. According to this, signals from the piezoelectric thin-film resonating unit can be input and output from a first substrate side while the signals are prevented from being coupled to the second substrate.

When the via conductor is formed as a structure for inputting and outputting signals of the piezoelectric thin-film resonating unit (acoustic wave resonating unit) by machining the substrate made of a piezoelectric material, degradation of signals of the acoustic wave resonating unit is a concern.

In contrast, a structure for inputting and outputting signals of the acoustic wave resonating unit by forming the via conductor in the lid substrate may be used. In this structure, however, to reduce or prevent the degradation of signals of the acoustic wave resonating unit, it is necessary to improve the joint strength of the support portion connected to the via conductor and the electrode of the piezoelectricity substrate while ensuring a space between the piezoelectricity substrate and the lid substrate.

### SUMMARY OF THE INVENTION

Example embodiments of the present invention provide acoustic wave devices each including support portion with improved joint strength.

According to an example embodiment of the present invention, an acoustic wave device includes a first substrate including a first main surface and a second main surface facing away from each other, a second substrate including a third main surface facing the first main surface, a functional electrode on the third main surface, a support portion between the first main surface and the third main surface to provide a space between the first main surface and the third main surface, and a via conductor located in the first substrate and extending from the first main surface toward the second main surface, in which the support portion includes a first metal film in contact with the via conductor and located on the first main surface, and a second metal film in contact with the first metal film and located on an opposite side of the via conductor with the first metal film therebetween, in plan view of the first main surface, a region of the first metal film includes a region of the second metal film, and an area of the first metal film is larger than an area of the second metal film, and a hardness of the second metal film is greater than a hardness of the first metal film.

According to example embodiments of the present invention, acoustic wave devices each including a support portion with improved joint strength are provided.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a cross-sectional view of an acoustic wave device according to an example embodiment of the present invention.

FIG. 2A is a first plan view of an acoustic wave device according to an example embodiment of the present invention.

FIG. 2B is a second plan view of an acoustic wave device according to an example embodiment of the present invention.

FIG. 2C is a third plan view of an acoustic wave device according to an example embodiment of the present invention.

FIG. 3A indicates a plan view and a cross-sectional view schematically illustrating a first example of an acoustic wave resonator of an acoustic wave device according to an example embodiment of the present invention.

FIG. 3B is a cross-sectional view schematically illustrating a second example of an acoustic wave resonator of an acoustic wave device according to an example embodiment of the present invention.

FIG. 3C is a cross-sectional view schematically illustrating a third example of an acoustic wave resonator of an acoustic wave device according to an example embodiment of the present invention.

FIG. 3D is a cross-sectional view schematically illustrating a fourth example of an acoustic wave resonator of an acoustic wave device according to an example embodiment of the present invention.

FIG. 4 is a cross-sectional view illustrating a via conductor of an acoustic wave device according to an example embodiment and surroundings thereof in an enlarged manner.

FIG. 5 is a cross-sectional view illustrating an example of a multilayer structure of metal films of an acoustic wave device according to an example embodiment of the present invention.

FIG. 6 is a cross-sectional view illustrating a multilayer interface of metal films of an acoustic wave device according to an example embodiment in an enlarged manner.

FIG. 7 is a cross-sectional view of an acoustic wave device according to modification 1 of an example embodiment of the present invention.

FIG. 8 is a first plan view of the acoustic wave device according to modification 1 of an example embodiment of the present invention.

FIG. 9 is a cross-sectional view of a support portion illustrating hardness measurement points.

FIG. 10A is a schematic cross-sectional view illustrating an interface between a via conductor and a first substrate of an acoustic wave device according to an example embodiment of the present invention.

FIG. 10B is a SEM image illustrating an interface between a via conductor and a first substrate of an acoustic wave device according to an example embodiment of the present invention.

FIG. 11A is a cross-sectional view of an acoustic wave device according to modification 2 of an example embodiment of the present invention.

FIG. 11B is a cross-sectional view of an acoustic wave device according to modification 3 of an example embodiment of the present invention.

FIG. 11C is a cross-sectional view of an acoustic wave device according to modification 4 of an example embodiment of the present invention.

FIG. 11D is a cross-sectional view of an acoustic wave device according to modification 5 of an example embodiment of the present invention.

FIG. 12 is a cross-sectional view illustrating a multilayer structure of metal films of an acoustic wave device according to modification 6 of an example embodiment of the present invention.

FIG. 13 is a cross-sectional view illustrating a multilayer structure of metal films of an acoustic wave device according to a comparative example.

### DETAILED DESCRIPTION OF THE EXAMPLE EMBODIMENTS

Example embodiments of the present invention will be described in detail below with reference to the drawings. The example embodiments described below illustrate comprehensive or specific examples. The numerical values, shapes, materials, components, disposition and connection configurations of components illustrated in the example embodiments described below are examples and are not intended to limit the present invention. Of the components in the following example embodiments, the components not described in the independent claim are described as optional components. In addition, the sizes or size ratios of components illustrated in the drawings are not necessarily accurate.

The drawings are schematic diagrams in which emphasis, omission, or adjustment of proportion has been provided as appropriate to describe example embodiments of the present invention and are not necessarily illustrated accurately, and the drawings do not necessarily represent actual shapes, positional relationships, and proportions. In the drawings, the same reference numerals are assigned to the same or substantially the same components, and redundant descriptions may be omitted or simplified.

In the circuit structure of example embodiments of the present invention, “connected” refers not only to direct connection between electrodes and/or wiring conductors but also to electric connection through matching elements, such as an inductor and a capacitor, and switch circuits. “Connected between A and B” means connection to both A and B between A and B.

In addition, terms that indicate the relationships between elements, such as “parallel” and “vertical”, terms that indicate the shapes of elements, such as “rectangular”, and numerical ranges do not only represent strict meanings but also substantially equivalent ranges, for example, ranges including an error of approximately a few percent.

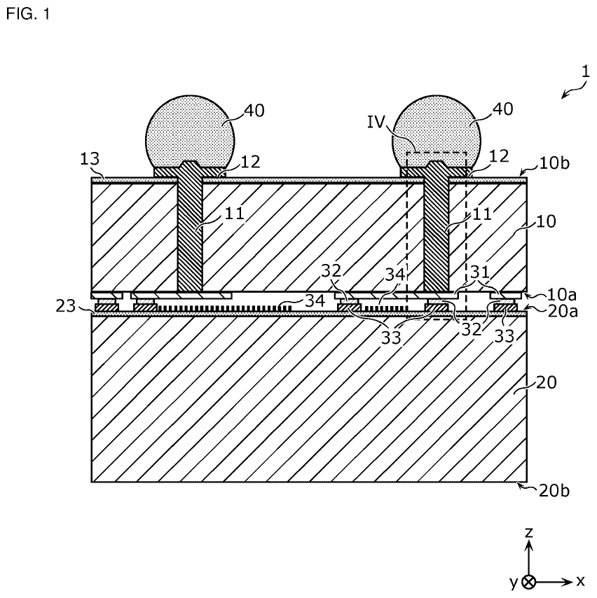

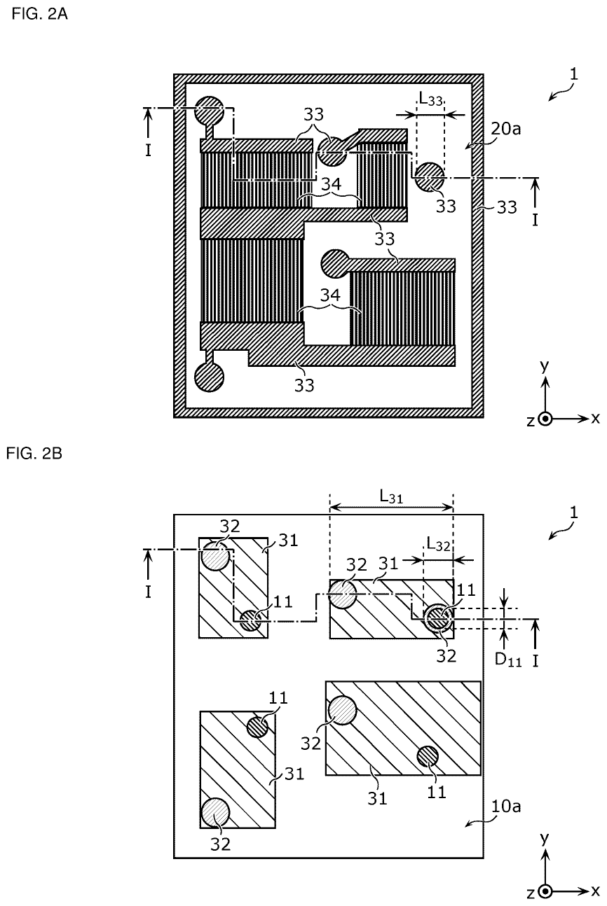

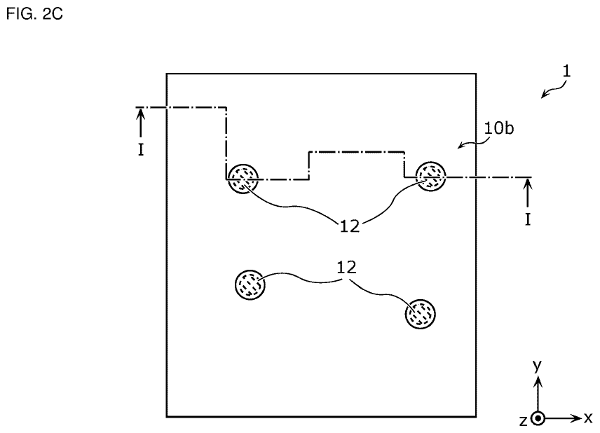

FIG. 1 is a cross-sectional view of an acoustic wave device 1 according to an example embodiment of the present invention. FIG. 2A is a first plan view of the acoustic wave device 1 according to the present example embodiment. FIG. 2B is a second plan view of the acoustic wave device 1 according to the present example embodiment. FIG. 2C is a third plan view of the acoustic wave device 1 according to the present example embodiment. FIG. 2A is a plan view (transparent view) of a main surface 20a of a substrate 20 as viewed from a Z-axis positive side, FIG. 2B is a plan view (transparent view) of a main surface 10a of a substrate 10 as viewed from the Z-axis positive side, and FIG. 2C is a plan view of a main surface 10b of the substrate 10 as viewed from the Z-axis positive side. FIG. 1 is a cross-sectional view taken along line I-I in FIGS. 2A, 2B, and 2C.

As illustrated in FIGS. 1 to 2C, the acoustic wave device 1 includes the substrates 10 and 20, metal films 31, 32, and 33, functional electrodes 34, a via conductor 11, insulation films 13 and 23, planar electrodes 12, and bump electrodes 40.

The substrate 10 is an example of the first substrate and includes a main surface 10a (first main surface) and a main surface 10b (second main surface) that face away from each other. In the present example embodiment, the substrate 10 includes silicon, for example.

The substrate 20 is an example of the second substrate and includes a main surface 20a (third main surface) and a main surface 20b that face away from each other. The main surface 10a and the main surface 20a face each other. In the present example embodiment, the substrate 20 has piezoelectricity.

As illustrated in FIG. 1, the via conductor 11 is an electrode disposed in the substrate 10 to extend from the main surface 10a toward the main surface 10b. In the present example embodiment, the via conductor 11 is a through-electrode that fills the cavities passing through the substrate 10 between the main surface 10a and the main surface 10b. The via conductor 11 includes a metal including, for example, copper as a main component.

The via conductor 11 does not need to be a single via conductor that extends from the main surface 10a to the main surface 10b and may have a structure in which a plurality of via conductors are connected to each other through a planar electrode provided in the substrate 10.

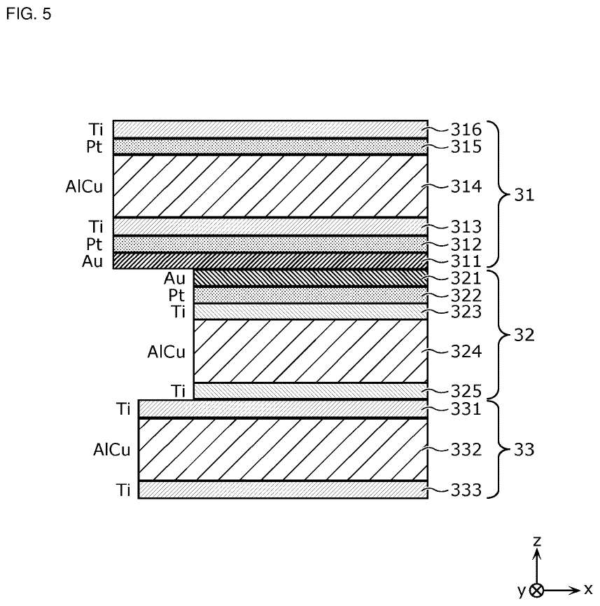

The metal film 31 is an example of the first metal film and, as illustrated in FIGS. 1 and 2B, is a planar electrode that is disposed on the main surface 10a and is in contact with the via conductor 11. The metal film 31 is, for example, a multilayer body including a plurality of metal layers. An example of the multilayer structure of the metal film 31 will be described in FIG. 5.

The metal film 32 is an example of the second metal film, and, as illustrated in FIGS. 1 and 2B, is a planar electrode that is disposed on the opposite side of the via conductor 11 with the metal film 31 therebetween and is in contact with the metal film 31. The metal film 32 is, for example, a multilayer body including a plurality of metal layers. An example of the multilayer structure of the metal film 32 will be described in FIG. 5.

The metal film 33 is an example of the third metal film and, as illustrated in FIGS. 1 and 2A, is a planar electrode that is disposed on the main surface 20a, connected to the functional electrode 34, and in contact with the metal film 32. The metal film 33 is, for example, a multilayer body including a plurality of metal layers. An example of the multilayer structure of the metal film 33 will be described in FIG. 5.

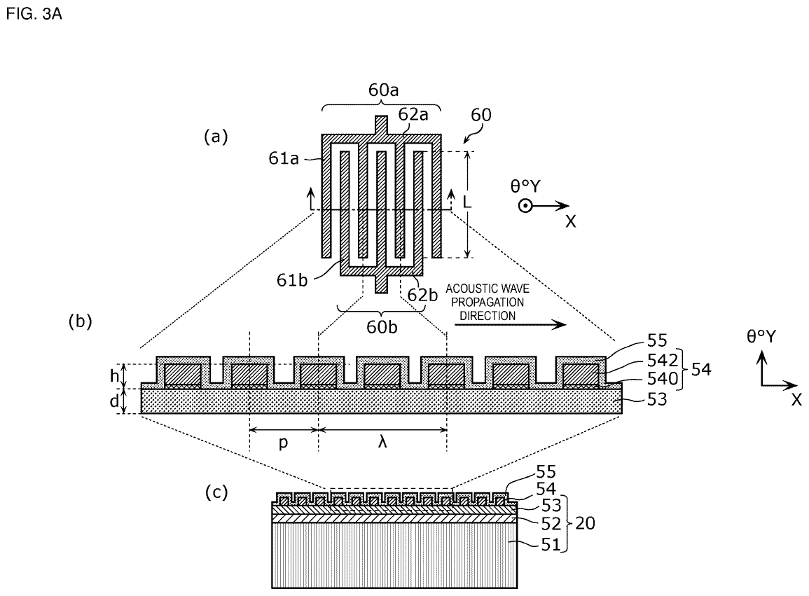

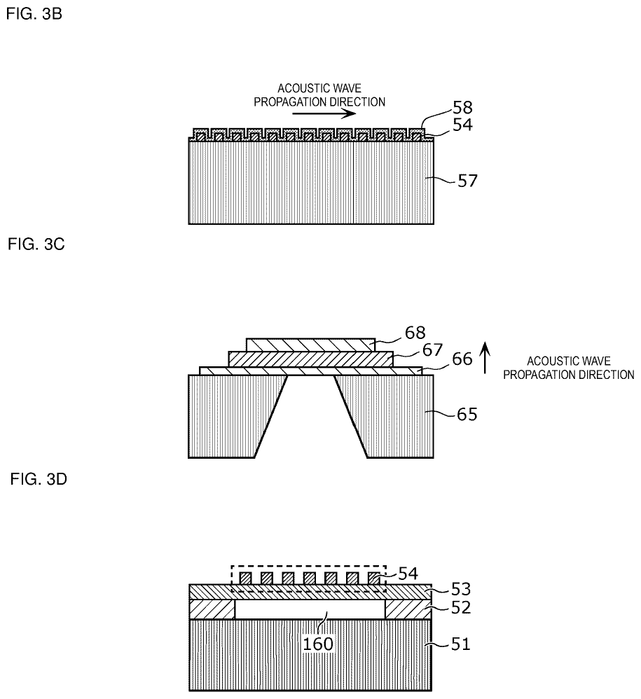

The functional electrode 34 is disposed on the main surface 20a and performs electromechanical transduction together with the substrate 20. Examples of the structures of the functional electrode 34 and the metal film 33 will be described in FIGS. 3A to 3D.

As illustrated in FIG. 1, the metal films 31, 32, and 33 define a support portion and are laminated and disposed in this order between the main surface 10a and the main surface 20a so as to provide a space between the main surface 10a and the main surface 20a.

The insulation film 13 is disposed on the main surface 10b and is, for example, a silicon oxide film. The insulation film 23 is disposed on the main surface 20a and is, for example, a silicon oxide film. At least one of the insulation films 13 and 23 may be omitted.

Next, an example of the structures of the substrate 20, the functional electrode 34, and the metal films 33 will be described. FIG. 3A indicates a plan view and a cross-sectional view schematically illustrating a first example of an acoustic wave resonator 60 of the acoustic wave device 1 according to the present example embodiment. The basic structure of the acoustic wave resonator 60 of the acoustic wave device 1 is illustrated in FIG. 3A. The acoustic wave resonator 60 illustrated in FIG. 3A is intended to describe the typical structure of the acoustic wave resonator of the acoustic wave device 1, and the number and the length of the electrode fingers of the electrodes are not limited to this example.

The acoustic wave resonator 60 includes the substrate 20 and interdigitated electrodes 60a and 60b.

As illustrated in part (a) of FIG. 3A, a pair of interdigitated electrodes 60a and 60b that face each other is provided on the substrate 20. The interdigitated electrode 60a includes a plurality of electrode fingers 61a (first electrode fingers) that are parallel to each other and a busbar electrode 62a (first busbar electrode) that connects one ends of the plurality of electrode fingers 61a to each other. In addition, the interdigitated electrode 60b includes a plurality of electrode fingers 61b (second electrode fingers) that are parallel to each other and a busbar electrode 62b (second busbar electrode) that connects one ends of the plurality of electrode fingers 61b to each other. The plurality of electrode fingers 61a and 61b are arranged in a direction orthogonal to the propagation direction (X-axis direction) of an acoustic wave. The busbar electrode 62a and the busbar electrode 62b are disposed to face each other with the electrode fingers 61a and 61b therebetween. The interdigitated electrodes 60a and 60b define an IDT (interdigital transducer) electrode 54.

Here, when the acoustic wave device 1 according to the present example embodiment performs electromechanical transduction by using the IDT electrode 54, the functional electrodes 34 illustrated in FIGS. 1 and 2A include the plurality of electrode fingers 61a and the plurality of electrode fingers 61b. In addition, the metal films 33 illustrated in FIGS. 1 and 2A include the busbar electrodes 62a and 62b.

The acoustic wave resonator 60 may include ends of the IDT electrode 54 in the propagation direction (X-axis direction) of an acoustic wave.

As illustrated in part (b) of FIG. 3A, the IDT electrode 54 has a multilayer structure including, for example, close contact layers 540 and main electrode layers 542.

The close contact layer 540 is a layer to improve the adhesion between the substrate 20 and the main electrode layer 542, and the material thereof is, for example, Ti. The material of the main electrode layer 542 is, for example, Al including about 1% Cu. The protective layer 55 covers the interdigitated electrodes 60a and 60b. The protective layer 55 is intended to protect the main electrode layers 542 from the external environment, adjust the frequency-temperature characteristics, and improve moisture resistance, and the protective layer 55 is a dielectric film including, for example, silicon dioxide as a main component.

The materials of the close contact layers 540, the main electrode layers 542, and the protective layer 55 are not limited to the materials described above. In addition, the IDT electrode 54 does not need to have the multilayer structure described above. The IDT electrode 54 may be made of a metal, such as, for example, Ti, Al, Cu, Pt, Au, Ag, or Pd or may include a plurality of multilayer bodies made of any of the metals or alloys thereof. In addition, the protective layer 55 is not necessarily provided.

Next, the multilayer structure of the substrate 20 will be described.

As illustrated in part (c) of FIG. 3A, the substrate 20 includes a support substrate 51, an intermediate layer 52, and a piezoelectric film 53, and has a structure in which the support substrate 51, the intermediate layer 52, and the piezoelectric film 53 are laminated together in this order.

The piezoelectric film 53 is made of, for example, a θ°Y-cut X-propagating LiTaO₃ piezoelectric single crystal or piezoelectric ceramic (a lithium tantalate single crystal or ceramic cut in a plane normal to the axis rotated θ° from the Y-axis with the X-axis as the central axis in which a surface acoustic wave propagates in the X-axis direction). The material and the cut angle θ of a piezoelectric single crystal used as the piezoelectric film 53 is selected as appropriate in accordance with the required specification of each filter.

The support substrate 51 supports the intermediate layer 52, the piezoelectric film 53, and the IDT electrode 54. The support substrate 51 may also be a substrate in which the acoustic velocity of a bulk wave in the support substrate 51 is higher than the acoustic velocity of an acoustic wave, such as a surface acoustic wave or a boundary acoustic wave propagating through the piezoelectric film 53, and the support substrate 51 defines and functions to confine the surface acoustic wave in a portion in which the piezoelectric film 53 and the intermediate layer 52 are laminated and to prevent the surface acoustic wave from leaking below the support substrate 51. The material of the support substrate 51 can be a piezoelectric body such as, for example, aluminum nitride, lithium tantalate, lithium niobate, or quartz, a ceramic such as alumina, sapphire, magnesia, silicon nitride, silicon carbide, zirconia, cordierite, mullite, steatite, forsterite, spinel, or sialon, a dielectric such as aluminum oxide, silicon oxynitride, diamond-like carbon (DLC), or diamond, or a semiconductor such as silicon, or a material including one of the materials described above as a main component. The spinel described above includes an aluminum compound including oxygen and one or more of Mg, Fe, Zn, or Mn, for example. Examples of the spinel described above can be MgAl₂O₄, FeAl₂O₄, ZnAl₂O₄, or MnAl₂O₄.

The intermediate layer 52 is, for example, a film in which the acoustic velocity of a bulk wave in the intermediate layer 52 is lower than the acoustic velocity of a bulk wave propagating through the piezoelectric film 53, and the intermediate layer 52 is disposed between the piezoelectric film 53 and the support substrate 51. This structure and the property that energy concentrates in a medium with essentially low acoustic velocity reduce or prevent the leakage of surface acoustic wave energy to the outside of the IDT electrode. The material of the intermediate layer 52 can be, for example, a dielectric such as glass, silicon oxide, silicon nitride, lithium oxide, tantalum oxide, or a compound in which fluorine, carbon, or boron is added to silicon oxide or a material including one of the materials described above as the main component can be used.

In the multilayer structure of the substrate 20, the Q value at the resonant frequency and the anti-resonant frequency can be made larger than that in the conventional structure in which a piezoelectric substrate is used as a single layer. That is, an acoustic wave resonator with a high Q value can be provided, and accordingly, a filter with low insertion loss can be provided by using this acoustic wave resonator.

The support substrate 51 may have a structure in which the support substrate and a high-velocity film in which the acoustic velocity of a propagating bulk wave is higher than the acoustic velocity of an acoustic wave, such as a surface acoustic wave and a boundary acoustic wave propagating through the piezoelectric film 53, are laminated together. In this case, the same material as the support substrate 51 can be used as the material of the high-velocity film. In addition, the material of the support substrate can be a piezoelectric body such as, for example, aluminum nitride, lithium tantalate, lithium niobate, or quartz, a ceramic such as alumina, sapphire, magnesia, silicon nitride, silicon carbide, zirconia, cordierite, mullite, steatite, or forsterite, a dielectric such as diamond or glass, or a semiconductor such as silicon or gallium nitride, a resin, or a material including one of the materials described above as a main component.

The wavelength λ of the acoustic wave resonator 60 is defined by the repeating period of the plurality of electrode fingers 61a or 61b of the IDT electrode 54 illustrated in part (b) of FIG. 3A. In addition, the electrode finger pitch p is about ½ of the wavelength λ and is defined as (W+S) where W is the line width of the electrode fingers 61a and 61b of the interdigitated electrodes 60a and 60b, and S is the space width between adjacent electrode fingers 61a and 61b. In addition, the electrode finger duty D of the IDT electrode 54, which is the line width occupancy ratio of the electrode fingers 61a and 61b and is the ratio of the line width W to the sum of the line width W and the space width S, is defined as W/(W+S). When the spacing between adjacent electrode fingers is not constant in the IDT electrode 54, the electrode finger pitch p of the IDT electrode 54 is defined by the average electrode finger pitch PAVE of the IDT electrode 54. The average electrode finger pitch PAVE of the IDT electrode 54 is defined as Di/(Ni−1) where Ni is the total number of electrode fingers 61a and 61b included in the IDT electrode 54, and Di is the center-to-center distance between the electrode finger located at one end and the electrode finger located at the other end in the propagation direction of an acoustic wave in the IDT electrode 54. In addition, when the electrode finger duty D is not constant in the IDT electrode 54, the electrode finger duty D of the IDT electrode 54 is defined by the average electrode finger duty D_{AVE} of the IDT electrode 54. The average electrode finger duty D_{AVE} of the IDT electrode 54 is defined as W_{ALL}/(W_{ALL}+S_{ALL}) where Ni is the total number of electrode fingers 61a and 61b included in the IDT electrode 54, W_{ALL} is the total line width obtained by adding the line widths W of (Ni−1) electrode fingers to each other, and S_{ALL} is the total space width obtained by adding the space widths S of (Ni−1) spaces included in the IDT electrode 54.

The electrode finger pitch p of the interdigitated electrode of the IDT electrode 54 can be measured by measuring the line width L and the space width S by observing, in plan view, the main surface of the substrate on which the interdigitated electrode of the IDT electrode 54 is provided and/or by observing, in cross-sectional view, a cross-section in a direction orthogonal to the extension direction of the electrode finger using a scanning electron microscope (SEM), a scanning transmission electron microscope (STEM), or a transmission electron microscope (TEM).

The term “main component of a material” in this specification refers to a component that accounts for more than 50 weight percent of the material. The main component described above may exist in any of a single-crystal state, a polycrystal state, and an amorphous state, or a state in which these are mixed.

FIG. 3B is a cross-sectional view schematically illustrating a second example of the acoustic wave resonator 60 of the acoustic wave device 1 according to an example embodiment of the present invention. An example in which the IDT electrode 54 is provided on the substrate 20 that includes the piezoelectric film 53 in the acoustic wave resonator 60 is illustrated in FIG. 3A, but the substrate on which the IDT electrode 54 is provided may also be a piezoelectric single-crystal substrate 57 including a single piezoelectric layer as illustrated in FIG. 3B.

The piezoelectric single-crystal substrate 57 includes, for example, a piezoelectric single crystal of LiNbO₃. The acoustic wave resonator according to the present example includes the piezoelectric single-crystal substrate 57 of LiNbO₃, the IDT electrode 54, and a protective layer 58 provided on the piezoelectric single-crystal substrate 57 and the IDT electrode 54.

The multilayer structures, the materials, the cut angles, and the thicknesses of the piezoelectric film 53 and the piezoelectric single-crystal substrate 57 may be changed as appropriate in accordance with the required bandpass characteristics of the acoustic wave device 1. Even an acoustic wave resonator using, for example, a LiTaO₃ piezoelectric substrate that uses a cut-angle other than the cut-angle described above can achieve advantageous effects the same as or similar to those of the acoustic wave resonator 60 that uses the piezoelectric film 53 described above.

In addition, a piezoelectric substrate on which the IDT electrode 54 is provided may have a structure in which the support substrate, the energy confinement layer, and the piezoelectric film are laminated together in this order. The IDT electrode 54 is provided on the piezoelectric film. For example, a LiTaO₃ piezoelectric single crystal or piezoelectric ceramic is used as the piezoelectric film. The support substrate supports the piezoelectric film, the energy confinement layer, and the IDT electrode 54.

The energy confinement layer includes one or more layers, and the velocity of a bulk acoustic wave propagating through at least one of these layers is greater than the velocity of an acoustic wave propagating the through vicinity of the piezoelectric film. For example, the energy confinement layer may have a multilayer structure including a low-velocity layer and a high-velocity layer. The low-velocity layer is a film in which the acoustic velocity of a bulk wave in the low-velocity layer is smaller than the acoustic velocity of an acoustic wave propagating through the piezoelectric film. The high-velocity layer is a film in which the acoustic velocity of a bulk wave in the high-velocity layer is greater than the acoustic velocity of an acoustic wave propagating through the piezoelectric film. The support substrate may also be the high-velocity layer.

In addition, the energy confinement layer may be an acoustic impedance layer having a structure in which a low-acoustic-impedance layer with relatively low acoustic impedance and a high-acoustic-impedance layer with relatively high acoustic impedance are alternately laminated together.

In addition, FIG. 3C is a cross-sectional view schematically illustrating a third example of an acoustic wave resonator 60 of the acoustic wave device 1 according to the present example embodiment. In FIG. 3C, a bulk acoustic wave resonator is illustrated as the acoustic wave resonator of the acoustic wave device 1. As illustrated in FIG. 3C, the bulk acoustic wave resonator includes, for example, a support substrate 65, a lower electrode 66, a piezoelectric layer 67, and an upper electrode 68 and has a structure in which the support substrate 65, the lower electrode 66, the piezoelectric layer 67, and the upper electrode 68 are laminated together in this order.

The support substrate 65 supports the lower electrode 66, the piezoelectric layer 67, and the upper electrode 68 and is, for example, a silicon substrate. The support substrate 65 includes a cavity in a region in contact with the lower electrode 66. As a result, the piezoelectric layer 67 can vibrate freely.

The lower electrode 66 is an example of the first planar electrode and is provided on one surface of the support substrate 65. The upper electrode 68 is an example of the second planar electrode and is provided on one surface of the support substrate 65. The lower electrode 66 and the upper electrode 68 are made of, for example, Al including about 1% Cu.

The piezoelectric layer 67 is an example of a piezoelectric thin film and is provided between the lower electrode 66 and the upper electrode 68. The piezoelectric layer 67 includes at least one of, for example, ZnO (zinc oxide), AlN (aluminum nitride), PZT (lead zirconate titanate), KN (potassium niobate), LN (lithium niobate), LT (lithium tantalate), quartz, or LiBO (lithium borate) as a main component.

The bulk acoustic wave resonator having the multilayer structure described above generates resonance by applying electrical energy between the lower electrode 66 and the upper electrode 68 and inducing a bulk acoustic wave in the piezoelectric layer 67. A bulk acoustic wave generated by the bulk acoustic wave resonator propagates between the lower electrode 66 and the upper electrode 68 in a direction orthogonal to the film surface of the piezoelectric layer 67. That is, the bulk acoustic wave resonator is a resonator that utilizes a bulk acoustic wave.

Here, when the acoustic wave device 1 according to the present example embodiment performs electromechanical transduction by using a bulk acoustic wave, the functional electrode 34 illustrated in FIGS. 1 and 2A includes the lower electrode 66, the piezoelectric layer 67, and the upper electrode 68. In addition, the substrate 20 illustrated in FIGS. 1 and 2A may include the support substrate 65 without having piezoelectricity.

FIG. 3D is a cross-sectional view schematically illustrating a fourth example of an acoustic wave resonator 60 of the acoustic wave device 1 according to the present example embodiment. In the acoustic wave device 1 in this example, the substrate 20 includes the support substrate 51, the intermediate layer 52, a void 160, and a piezoelectric film 53.

In the acoustic wave device 1 in the present example, in plan view of the main surface 20a, the void 160 is provided between the piezoelectric film 53 and the support substrate 51 in the region that overlaps the IDT electrode 54. In addition, the normalized film thickness d/p of the piezoelectric film 53 is, for example, about 0.5 or less where d is the thickness of the piezoelectric film 53 (in the Z-axis direction), and p is the electrode finger pitch of the IDT electrode 54.

Since the normalized film thickness d/p of the piezoelectric film 53 is, for example, 0.5 or less, and the void 160 is provided, the acoustic wave resonator 60 defines a laterally excited bulk acoustic resonator (XBAR). Since the normalized film thickness d/p of the piezoelectric film 53 is, for example, about 0.5 or less, the fractional band width of the acoustic wave resonator 60 can be increased, and a resonator with a high electromechanical coupling coefficient can be formed.

The normalized film thickness d/p of the piezoelectric film 53 is more preferably about 0.24 or less, for example. As a result, the fractional band width of the acoustic wave resonator 60 can be about 7% or more.

The electrode finger duty D and the normalized film thickness d/p of the IDT electrode 54 preferably satisfy the relationship defined by equation 1.

$$D \leq 1.75 ( d / p ) + 0.075 \qquad ( Equation 1 )$$

As a result, the spurious response of the high-order mode of the XBAR can be effectively reduced. Specifically, for example, the fractional band width (the value obtained by dividing the differential frequency between the anti-resonant frequency and the resonant frequency by the average frequency of the anti-resonant frequency and the resonant frequency) of the XBAR can be about 17% or less, and inclusion of the spurious response of the higher-order mode within the pass band can be reduced or prevented.

In addition, the electrode finger duty D and the normalized film thickness d/p of the IDT electrode 54 preferably satisfy the relationship of equation 2.

$$D \leq 1.75 ( d / p ) + 10.05 \qquad ( Equation 2 )$$

As a result, the fractional band width of the XBAR can be, for example, about 17% or less with certainty, and inclusion of the spurious response of the high-order mode in the pass band can be reduced or prevented.

In addition, the piezoelectric film 53 is preferably made of lithium niobate or lithium tantalate, for example, and the Euler angles (θ1, θ2, θ3) of the lithium niobate or lithium tantalate constituting the piezoelectric film 53 desirably fall within the ranges defined by equations 3, 4, 5, or 6.

$$- 10 ° \leq θ 1 \leq 10 ° and 0 ° \leq θ 2 \leq 20 ° \qquad ( Equation 3 )$$

$$- 10 ° \leq θ 1 \leq 10 ° , 20 ° \leq θ 2 \leq 80 ° , and \qquad ( Equation 4 )$$

$$0 ° \leq θ 3 \leq 60 {° ( 1 - {( θ 2 - 50 )}^{2} / 900 )}^{1 / 2} )$$

$$- 10 ° \leq θ 1 \leq 10 ° , 20 ° \leq θ 2 \leq 80 ° , and \qquad ( Equation 5 )$$

$$[ 180 ° - 60 {° ( 1 - {( θ 2 - 50 )}^{2} / 900 )}^{1 / 2} ) ] \leq θ 3 \leq 180 °$$

$$- 10 ° \leq θ 1 \leq 10 ° and \qquad ( Equation 6 )$$

$$[ 180 ° - 30 {° ( 1 - {( θ 3 - 90 )}^{2} / 8100 )}^{1 / 2} ) ] \leq θ 2 \leq 180 °$$

By the Euler angles of the piezoelectric film 53 made of lithium niobate or lithium tantalate being defined as described above, the fractional band width of the acoustic wave resonator 60 can be, for example, about 5% or more.

In the acoustic wave device 1 in the fourth example, an energy confinement layer including a low-acoustic-impedance layer and a high-acoustic-impedance layer may be provided instead of the void 160. Specifically, an energy confinement layer having a structure in which a low-acoustic-impedance layer with relatively low acoustic impedance and a high-acoustic-impedance layer with relatively high acoustic impedance are alternately laminated together may be provided between the piezoelectric film 53 and the support substrate 51. The energy confinement layer may have a multilayer structure including a low-velocity film and a high-velocity film. The low-velocity film is a film in which the acoustic velocity of a bulk wave in the low-velocity film is smaller than the acoustic velocity of a bulk acoustic wave propagating through the piezoelectric film 53. The high-velocity film is a film in which the acoustic velocity of a bulk wave in the high-velocity film is greater than the acoustic velocity of an acoustic wave propagating through the piezoelectric film 53. Since the normalized film thickness d/p of the piezoelectric film 53 is, for example, about 0.5 or less, and the energy confinement layer is provided, the acoustic wave resonator 60 defines an XBAR.

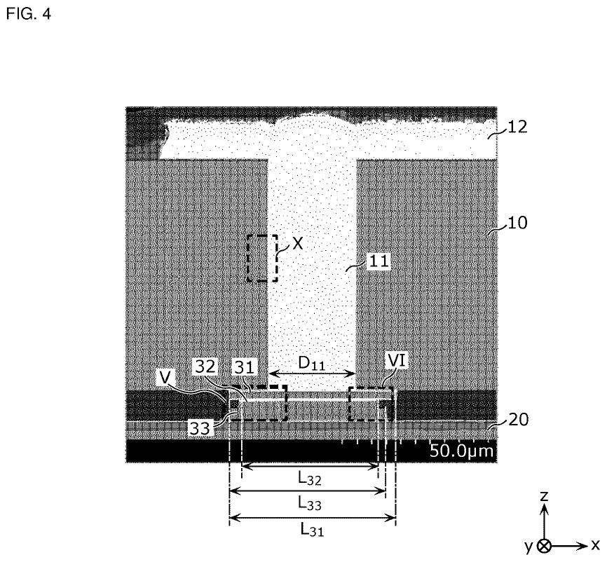

Next, the joint structure of the substrate 10, the via conductor 11, and the metal films 31 to 33 will be described. FIG. 4 is a cross-sectional view illustrating the via conductor 11 of the acoustic wave device 1 according to the present example embodiment and surroundings thereof in an enlarged manner. FIG. 4 illustrates a microscopic image in region IV in FIG. 1. As illustrated in FIG. 4, the via conductor 11 is provided in the substrate 10, a planar electrode 12 is joined to the upper (Z-axis positive direction) opening of the via conductor 11, and the metal film 31 is joined to the lower (Z-axis negative direction) opening of the via conductor 11. In addition, the metal film 32, the metal film 33, and the substrate 20 are joined together in this order to the Z-axis negative side of the metal film 31.

Here, as illustrated in FIG. 2B, in plan view of the main surface 10a, the region of the metal film 31 (in the upper right in FIG. 2B) includes the region of the via conductor 11 (in the upper right in FIG. 2B), and the area of the metal film 31 (in the upper right in FIG. 2B) is larger than the area of the via conductor 11 (in the upper right in FIG. 2B). In addition, in plan view of the main surface 10a, the region of the metal film 32 (in the upper right in FIG. 2B) includes the region of the via conductor 11 (in the upper right in FIG. 2B), and the area of the metal film 32 (in the upper right in FIG. 2B) is larger than the area of the via conductor 11 (in the upper right in FIG. 2B).

In other words, as illustrated in FIG. 4, in a cross-section (cross-section taken along line I-I in FIGS. 2A to 2C), in a direction (Z-axis direction) orthogonal to the main surface 10a, that passes through the via conductor 11, length L₃₁ of the metal film 31 is greater than length Du (diameter) of the via conductor 11, and length L₃₂ of the metal film 32 is greater than length Du (diameter) of the via conductor 11.

When the regions of the metal films 31 and 32 are included in the region of the via conductor 11 in plan view of the main surface 10a, the compressive stress of the metal films 31 and 32 is all applied to the via conductor 11, and the via conductor 11 may deform or the via conductor 11 may peel off from the substrate 10. In contrast, in the structure of the acoustic wave device 1 according to the present example embodiment, in plan view of the main surface 10a, the region of the via conductor 11 is included in the regions of the metal films 31 and 32, and the area of the metal film 31 is larger than the area of the via conductor 11, and the area of the metal film 32 is larger than the area of the via conductor 11. As a result, since the substrate 10 adjacent to the via conductor 11 in the X-axis direction is joined to the metal film 31, the substrate 10 joined to the metal film 31 absorbs the compressive stress of the metal films 31 and 32 and can reduce or prevent the via conductor 11 from deforming and peeling off. In other words, the fixation of the via conductor 11 can be improved. In addition, since the metal film 32 is joined to the metal film 33, and the metal film 33 is joined to the substrate 20, the compressive stress generated in the metal films 31 and 32 can be distributed to a substrate 20 side as well. Accordingly, the acoustic wave device 1 including the via conductor 11 with improved joint strength can be provided.

It should be noted that “region A includes region B” in this specification means that “the entirety or substantially the entirety of region B is disposed within region A”.

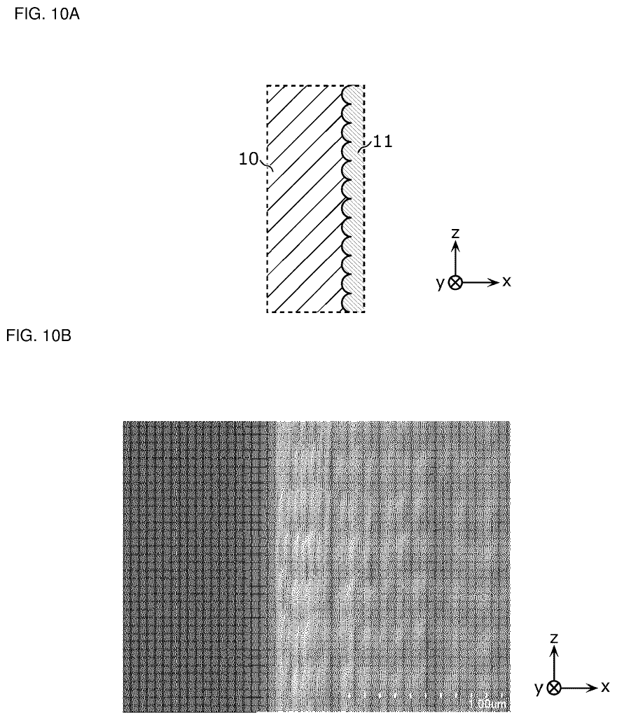

Next, the joint state between the via conductor 11 and the substrate 10 will be described. FIG. 10A is a schematic cross-sectional view illustrating the interface between the via conductor 11 and the substrate 10 of the acoustic wave device 1 according to the present example embodiment. FIG. 10B is a SEM image illustrating the interface between the via conductor 11 and the substrate 10 of the acoustic wave device 1 according to the present example embodiment. FIG. 10A is a cross-sectional view schematically illustrating region X in FIG. 4 in an enlarged manner.

In the process of forming, in the substrate 10 made of Si, for example, a cylindrical cavity that is filled with the via conductor 11, a conchoidal uneven structure known as a scallop is formed on the inner wall of the cylindrical cavity of the substrate 10. In the scallop uneven structure, when the tips of convex portions become acute, the electrical resistance at the tips of the uneven structure increases and heat generation is likely to occur, thus reducing the joint strength of the via conductor 11.

In the acoustic wave device 1 according to the present example embodiment, the peak-to-valley (PV) value of the scallop uneven structure is preferably about 100 μm or less, for example. The PV value is defined as the height difference between the highest point of the tips of the convex portions and the lowest point of the valleys of the concave portions of the uneven structure. In the acoustic wave device 1 according to the present example embodiment, as illustrated in FIGS. 10A and 10B, the tips of the convex portions of the scallop uneven structure are flattened. As a result, since heating can be reduced or prevented by reducing the electrical resistance at the tips of the uneven structure, and the generation of voids at the interface between the via conductor 11 and the substrate 10 can be reduced or prevented, the joint strength of the via conductor 11 can be improved.

Next, the multilayer structures of the metal films 31 to 33 will be described. FIG. 5 is a cross-sectional view illustrating an example of the multilayer structures of the metal films 31 to 33 constituting the acoustic wave device 1 according to the example embodiment. The drawing is a cross-sectional view schematically illustrating region V in FIG. 4 in an enlarged manner.

As illustrated in FIG. 5, the metal film 31 includes an intermediate layer 316, an intermediate layer 315, a main electrode layer 314, an intermediate layer 313, an intermediate layer 312, and a joint layer 311 in order from a main surface 10a side.

The intermediate layer 313 (first intermediate layer) and the intermediate layer 316 are metal layers including, for example, titanium (Ti) as a main component and define and function as diffusion barrier layers.

The intermediate layer 312 and the intermediate layer 315 are metal layers including, for example, platinum (Pt) as a main component and define and function as diffusion barrier layers together with the intermediate layers 313 and 316.

The main electrode layer 314 is an example of the first main electrode layer, is a metal layer including, for example, aluminum (Al) and copper (Cu) as main components, and defines and functions as a main medium through which a high-frequency signal is transmitted in the metal film 31.

The joint layer 311 is an example of the first joint layer, is a metal layer including, for example, gold (Au) as a main component, and has the function of providing good electrical and mechanical joint with the metal film 32.

The intermediate layers 312 and 315 may be omitted in the metal film 31 according to the present example embodiment. In addition, the metal film 31 may include only the main electrode layer 314.

In addition, as illustrated in FIG. 5, the metal film 32 includes a joint layer 321, an intermediate layer 322, an intermediate layer 323, a main electrode layer 324, and an intermediate layer 325 in order from the main surface 10a side.

The joint layer 321 is an example of the second joint layer, is a metal layer including, for example, gold (Au) as a main component, and has the function of providing good electrical and mechanical joint with the metal film 31.

The intermediate layer 322 is a metal layer including, for example, platinum (Pt) as a main component and defines and functions as a diffusion barrier layer together with the intermediate layer 323.

The intermediate layer 323 (second intermediate layer) and the intermediate layer 325 are metal layers including, for example, titanium (Ti) as a main component and define and function as diffusion barrier layers.

The main electrode layer 324 is an example of the second main electrode layer, is a metal layer including, for example, aluminum (Al) and copper (Cu) as main components, and defines and functions as a main medium through which a high-frequency signal is transmitted in the metal film 32.

The intermediate layer 322 may be omitted in the metal film 32 according to the present example embodiment. In addition, the metal film 32 may include only the main electrode layer 324.

In addition, as illustrated in FIG. 5, the metal film 33 includes an intermediate layer 331, a main electrode layer 332, and an intermediate layer 333 in order from the main surface 10a side.

The intermediate layers 331 and 333 are metal layers including, for example, titanium (Ti) as a main component and define and function as diffusion barrier layers.

The main electrode layer 332 is a metal layer including, for example, aluminum (Al) and copper (Cu) as main components and defines and functions as a main medium through which a high-frequency signal is transmitted in the metal film 33.

The intermediate layers 331 and 333 may be omitted in the metal film 33 according to the present example embodiment, and the metal film 33 may include only the main electrode layer 332.

The main electrode layer 332 in FIG. 5 corresponds to, for example, the main electrode layer 542 in FIG. 3A, and the intermediate layer 333 in FIG. 5 corresponds to, for example, the close contact layer 540 in FIG. 3A.

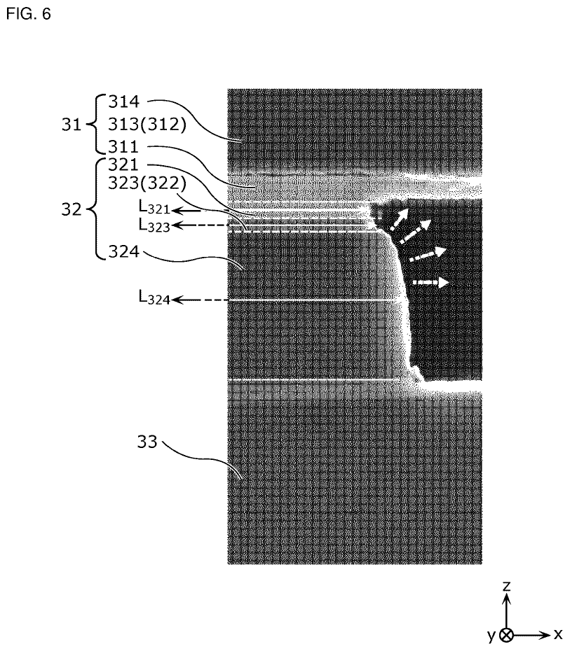

The magnitude relationship of the areas (and the lengths) of the metal layers defining each of the metal films is not limited to the magnitude relationship of the areas (and the lengths) of the metal layers illustrated in FIG. 5. The relationship of the areas (and lengths) of the metal layers will be described with reference to FIG. 6.

In addition, as illustrated in FIG. 2B, in plan view of the main surface 10a, the region of the metal film 31 (in the upper right in FIG. 2B) includes the region of the metal film 32 (in the upper right in FIG. 2B), and the area of the metal film 31 (in the upper right in FIG. 2B) is larger than the area of the metal film 32 (in the upper right in FIG. 2B).

In other words, as illustrated in FIG. 4, in the cross-section (cross-section taken along line I-I in FIGS. 2A to 2C), in the direction (Z-axis direction) orthogonal to the main surface 10a, that passes through the via conductor 11, length L₃₁ of the metal film 31 is greater than length L₃₂ of the metal film 32.

As a result, since the joint of the metal film 32 does not deform the shape of the end portion of the metal film 31, the joint between the substrate 10 and the metal film 31 can reduce or prevent in the compressive stress applied to the via conductor 11.

In addition, the hardness of the metal film 32 is greater than the hardness of the metal film 31.

When two metal films are joined to each other, if the hardness of one of the two metal films with a smaller area is lower, the metal film with a smaller area is crushed and protrudes to the end portion of the joint interface during pressure joint, the joint portion is locally heated due to the metal film having protruded to the end portion, the joint portion degrades, and the metal film having protruded to the end portion becomes unnecessary grains.

In contrast, in the acoustic wave device 1 according to the present example embodiment, the hardness of the metal film 32 with a smaller area is greater than the hardness of the metal film 31 with a larger area in plan view of the main surface 10a. Accordingly, the metal film 32 with a smaller area can be reduced or prevented from being crushed during pressure joining of the metal films 31 and 32, thus enabling a joint that wraps the metal film 32 with a smaller area with the metal film 31 with a larger area. Accordingly, it is possible to provide the acoustic wave device 1 that can reduce or prevent local heating and generation of unnecessary grains at the end portion of the joint interface and includes the support portions with improved joint strength.

In addition, as illustrated in FIG. 2A and FIG. 2B, in plan view of the main surface 20a, the region of the metal film 33 includes the region of the metal film 32, and the area of the metal film 33 is larger than the area of the metal film 32.

In other words, as illustrated in FIG. 4, in the cross-section (cross-section taken along line I-I in FIGS. 2A to 2C), in a direction (Z-axis direction) orthogonal to the main surface 20a, that passes through the via conductor 11, length L₃₃ of the metal film 33 is greater than length L₃₂ of the metal film 32.

As a result, the positional layout of the functional electrode 34 and the metal film 33 can be prioritized without the metal film 32 restricting the areas of the functional electrode 34 and the metal film 33 on the main surface 20a.

In addition, the hardness of the metal film 33 preferably greater than the hardness of the metal film 31.

As a result, joint that wraps the metal films 32 and 33 with the metal film 31 can be achieved. Accordingly, it is possible to provide the acoustic wave device 1 that can reduce or prevent local heating and generation of unnecessary grains at the end portion of the joint interface and includes the support portions with improved joint strength.

In addition, the element with the highest weight ratio of the metal elements of the joint layer 321 is preferably the same as the element with the highest weight ratio of the metal elements of the joint layer 311. In the present example embodiment, the joint layers 311 and 321 are metal layers including, for example, Au as a main component. The element (Au) with the highest weight ratio in the joint layer 321 is the same as the element (Au) with the highest weight ratio in the joint layer 311.

As a result, an Au diffusion joint can improve the joint strength of the metal film 31 and the metal film 32, thus improving the strength of the support portion.

In addition, the size of crystal grains of the joint layer 311 and the size of crystal grains of the joint layer 321 are preferably the same or substantially the same as each other.

Since the hardness of the metal film 31 differs from the hardness of the metal film 32 when the sizes of the crystal grains of the joint layers 311 and 321 differ from each other, the metal film with lower hardness is deformed during pressure joining, and a sufficient joint strength cannot be obtained. In contrast, since the hardnesses of the metal layers at the joint interface become the same or substantially the same as each other when the sizes of the crystal grains are the same or substantially the same to each other, a sufficient joint strength can be obtained without the metal films being deformed during pressure joining.

The size of crystal grains of a metal layer can be classified in accordance with, for example, the international standard ASTM E112-13. The metal layers are assigned grain size numbers in accordance with average grain diameters specified by the international standard described above. Here, the metal layers having the same or substantially the same grain size number are determined to have the same or substantially the same crystal grain size.

In addition, the surface roughness Ra of each of the joint layers 311 and 321 at the joint interface therebetween is preferably about 10 nm or less, for example.

As a result, since voids at the joint interface between the joint layers 311 and 321 can be eliminated, the joint strength of the joint layers 311 and 321 can be further improved.

Next, the conditions for improving the joint strength of the metal films that define the support portion will be described. FIG. 6 is a cross-sectional view illustrating a joint interface between the metal films 31 and 32 of the acoustic wave device 1 according to the present example embodiment in an enlarged manner. FIG. 6 is an enlarged microscopic image of region VI in FIG. 4. In the multilayer structure of the metal films illustrated in FIG. 6, the intermediate layers 313 and 312 are indicated as a single layer (intermediate layer 313(312)), and the intermediate layers 323 and 322 are indicated as a single layer (intermediate layer 323(322)). The intermediate layers 312 and 322 may be omitted.

First, as described above, in plan view of the main surface 10a, the region of the metal film 31 includes the region of the metal film 32, and the area of the metal film 31 is larger than the area of the metal film 32. In addition, as illustrated in FIG. 6, in plan view of the main surface 10a, the region of the intermediate layer 323(322) includes the region of the joint layer 321, and the area of the intermediate layer 323(322) is larger than the area of the joint layer 321. In addition, in plan view of the main surface 10a, the region of the main electrode layer 324 includes the region of the intermediate layer 323(322), and the area of the main electrode layer 324 is larger than the area of the intermediate layer 323(322). In other words, as illustrated in FIG. 6, in the cross-section (cross-section taken along line I-I in FIGS. 2A to 2C), in the direction orthogonal to the main surface 10a, that passes through the metal films 31 to 33, length L₃₂₃ of the intermediate layer 323(322) is greater than length L₃₂₁ of the joint layer 321, and length L₃₂₄ of the main electrode layer 324 is greater than length L₃₂₃ of the intermediate layer 323(322).

In addition, the linear expansion coefficient of the joint layer 321 is greater than the linear expansion coefficient of the intermediate layer 323(322), and the linear expansion coefficient of the main electrode layer 324 is greater than the linear expansion coefficient of the joint layer 321.

According to the multilayer relationship of the metal layers of the metal films 31 and 32, when the metal film 31 and the metal film 32 are heated during pressure joining, the main electrode layer 324 with a relatively large linear expansion coefficient has a larger area than the intermediate layer 323(322) and the joint layer 321. As a result, at the end portions of the main electrode layer 324 and the intermediate layer 323(322), the main electrode layer 324 and the intermediate layer 323(322) have a bimetal structure, and the main electrode layer 324 and the intermediate layer 323(322) are likely to expand toward the joint layer 321 (in the Z-axis positive direction) at the end portions. As a result, since both ends of the main electrode layer 324 are pushed up toward the metal film 31 (in the Z-axis positive direction), a good joint can be obtained at the joint end of the metal film 32.

An example of a method for measuring the hardness of the metal films 31 to 33 will be described.

The hardness of the metal films 31 to 33 can be measured by using, for example, the nanoindentation method. The nanoindentation (NI) method measures the hardness of an object by pressing a super small indenter into the object and obtaining the load-displacement curve of the object. FIG. 9 is a cross-sectional view of a support portion in which hardness measurement points are indicated. As illustrated in FIG. 9, a micro-indenter is pressed into the hardness measurement points on the side surfaces of the metal films 31 to 33. Examples of hardness measurement data are illustrated in Table 1. The device used was the Tribo Indenter TI980 manufactured by Bruker Japan K.K., and the measurement mode (load time, hold time, unload time) was standard (about 5 sec, about 2 sec, about 5 sec), the indenter load was about 400 UN, and the number of measurement points was 5 for each metal film.

TABLE 1

| Hardness | | Measurement | Measurement | Measurement | Measurement | Measurement |
|---|---|---|---|---|---|---|
| (GPa) | Average | Point 1 | Point 2 | Point 3 | Point 4 | Point 5 |
| Metal | 1.26 | 1.19 | 1.46 | 1.25 | 1.33 | 1.08 |
| Film 31 | | | | | | |
| Metal | 1.54 | 1.57 | 1.43 | 1.38 | 1.73 | 1.61 |
| Film 32 | | | | | | |
| Metal | 1.55 | 1.50 | 1.59 | 1.58 | 1.48 | 1.61 |
| Film 33 | | | | | | |

Table 1 indicates that the hardness of the metal film 32 is higher than the hardness of the metal film 31, and the hardness of the metal film 33 is higher than the hardness of the metal film 31, as a result of measurement of the hardness of the metal films 31 to 33 of the acoustic wave device 1 by using the NI method.

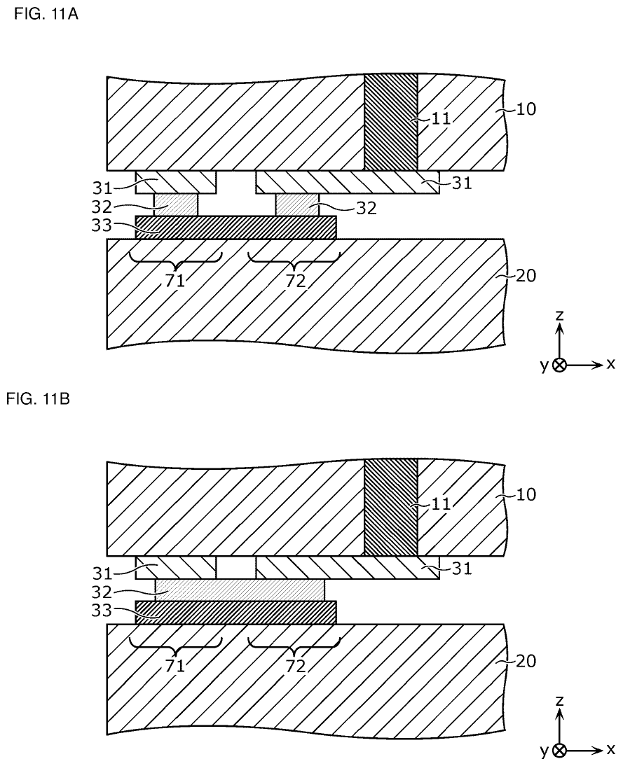

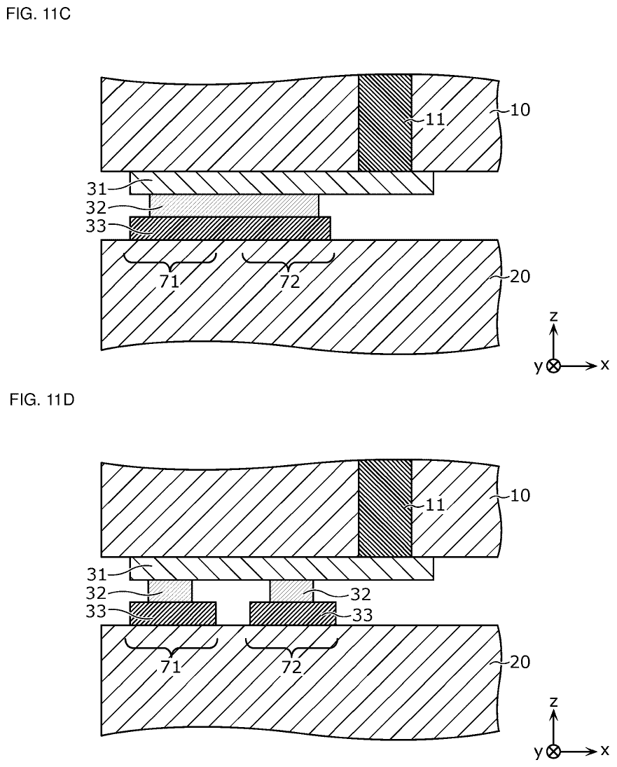

The structure of the support portion of the acoustic wave device 1 according to the present example embodiment is not limited to the structure illustrated in FIG. 1 and may have the structures illustrated in FIGS. 11A to 11D below.

FIG. 11A is a cross-sectional view of an acoustic wave device according to modification 2 of an example embodiment of the present invention. FIG. 11A is a cross-sectional view illustrating a portion of the substrate 10, a portion of the substrate 20, and the support portions 71 and 72 of the acoustic wave device according to modification 2. As illustrated in FIG. 11A, the acoustic wave device according to the present modification includes the substrates 10 and 20, the via conductor 11, and the support portions 71 and 72. The support portion 71 includes the metal film 31, not in contact with the via conductor 11, that is disposed on the main surface 10a, the metal film 33 disposed on the main surface 20a, and the metal films 32 disposed between the metal films 31 and 33. The support portion 72 includes the metal film 31, in contact with the via conductor 11, that is disposed on the main surface 10a, the metal film 33 disposed on the main surface 20a, and the metal film 32 disposed between the metal films 31 and 33. In the present modification, the metal film 31 of the support portion 71 and the metal film 31 of the support portion 72 are separated from each other, the metal film 32 of the support portion 71 and the metal film 32 of the support portion 72 are separated from each other, and the metal film 33 of the support portion 71 and the metal film 33 of the support portion 72 are integrated with each other.

As a result, since the metal film 33 is shared by the support portions 71 and 72, the manufacturing process of the acoustic wave device can be simplified.

FIG. 11B is a cross-sectional view of an acoustic wave device according to modification 3 of an example embodiment of the present invention. FIG. 11B a cross-sectional view illustrating a portion of the substrate 10, a portion of the substrate 20, and the support portions 71 and 72 of the acoustic wave device according to the present modification. As illustrated in FIG. 11B, the acoustic wave device according to the present modification includes the substrates 10 and 20, the via conductor 11, and the support portions 71 and 72. The support portion 71 includes the metal film 31, not in contact with the via conductor 11, that is disposed on the main surface 10a, the metal film 33 disposed on the main surface 20a, and the metal film 32 disposed between the metal films 31 and 33. The support portion 72 includes the metal film 31, in contact with the via conductor 11, that is disposed on the main surface 10a, the metal film 33 disposed on the main surface 20a, and the metal film 32 disposed between the metal films 31 and 33. In the present modification, the metal film 31 of the support portion 71 and the metal film 31 of the support portion 72 are separated from each other, the metal film 32 of the support portion 71 and the metal film 32 of the support portion 72 are integrated with each other, and the metal film 33 of the support portion 71 and the metal film 33 of the support portion 72 are integrated with each other.

As a result, since the metal film 32 is shared by the support portions 71 and 72, and the metal film 33 is shared by the support portions 71 and 72, the manufacturing process of the acoustic wave device can be simplified.

FIG. 11C is a cross-sectional view of an acoustic wave device according to modification 4 of an example embodiment of the present invention. FIG. 11C is a cross-sectional view illustrating a portion of the substrate 10, a portion of the substrate 20, and the support portions 71 and 72 of the acoustic wave device according to the present modification. As illustrated in FIG. 11C, the acoustic wave device according to the present modification includes the substrates 10 and 20, the via conductor 11, and the support portions 71 and 72. The support portion 71 includes the metal film 31 disposed on the main surface 10a, the metal film 33 disposed on the main surface 20a, and the metal film 32 disposed between the metal films 31 and 33. The support portion 72 includes the metal film 31, in contact with the via conductor 11, that is disposed on the main surface 10a, the metal film 33 disposed on the main surface 20a, and the metal film 32 disposed between the metal films 31 and 33. In the modification, the metal film 31 of the support portion 71 and the metal film 31 of the support portion 72 are integrated with each other, the metal film 32 of the support portion 71 and the metal film 32 of the support portion 72 are integrated with each other, and the metal film 33 of the support portion 71 and the metal film 33 of the support portion 72 are integrated with each other.

As a result, since the metal film 31 is shared by the support portions 71 and 72, the metal film 32 is shared by the support portions 71 and 72, and the metal film 33 is shared by the support portions 71 and 72, the manufacturing process of the acoustic wave device can be simplified.

FIG. 11D is a cross-sectional view of an acoustic wave device according to modification 5 of an example embodiment of the present invention. FIG. 11D is a cross-sectional view illustrating a portion of the substrate 10, a portion of the substrate 20, and the support portions 71 and 72 of the acoustic wave device according to the present modification. As illustrated in FIG. 11D, the acoustic wave device according to the present modification includes the substrates 10 and 20, the via conductor 11, and the support portions 71 and 72. The support portion 71 includes the metal film 31 disposed on the main surface 10a, the metal film 33 disposed on the main surface 20a, and the metal film 32 disposed between the metal films 31 and 33. The support portion 72 includes the metal film 31, in contact with the via conductor 11, that is disposed on the main surface 10a, the metal film 33 disposed on the main surface 20a, and the metal film 32 disposed between the metal films 31 and 33. In the present modification, the metal film 31 of the support portion 71 and the metal film 31 of the support portion 72 are integrated with each other, the metal film 32 of the support portion 71 and the metal film 32 of the support portion 72 are separated from each other, and the metal film 33 of the support portion 71 and the metal film 33 of the support portion 72 are separated from each other.

As a result, since the metal film 31 is shared by the support portions 71 and 72, the manufacturing process of the acoustic wave device can be simplified.

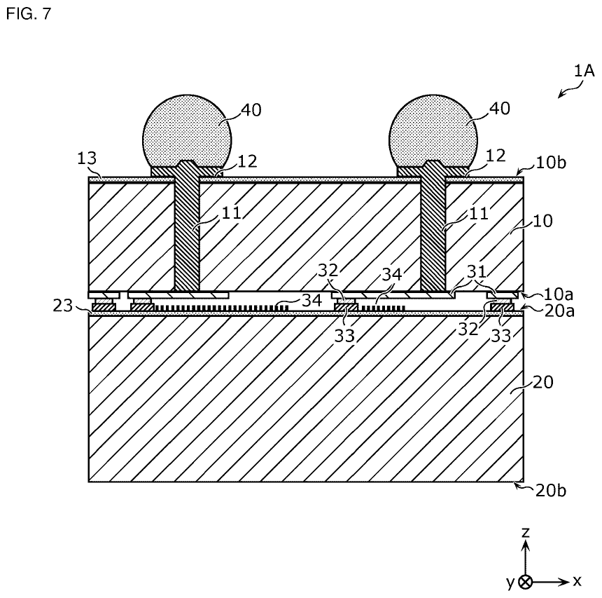

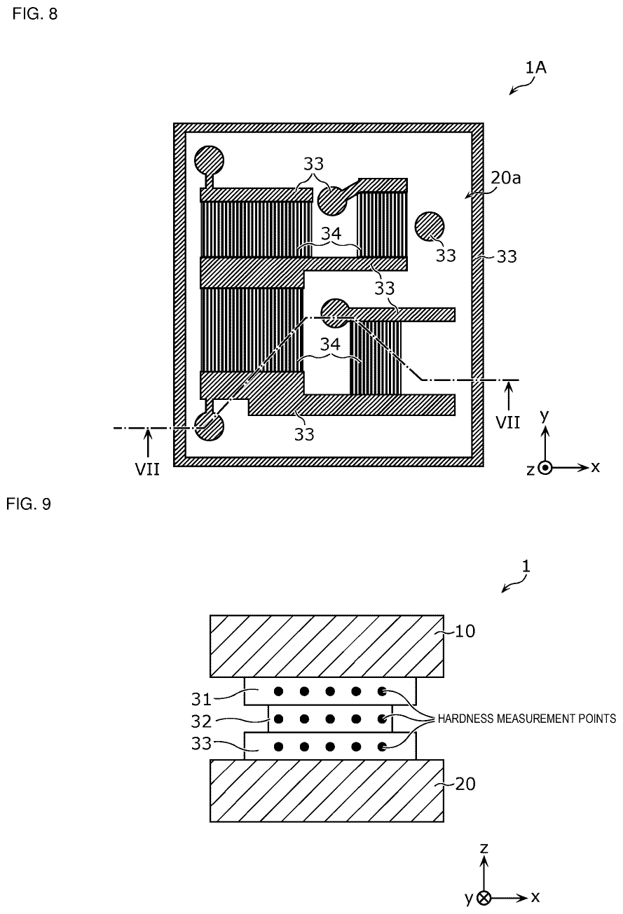

FIG. 7 is a cross-sectional view of an acoustic wave device 1A according to modification 1 of an example embodiment of the present invention. FIG. 8 is a first plan view of the acoustic wave device 1A according to modification 1. FIG. 8 is a plane view (transparent view) of the main surface 20a of the substrate 20 as viewed from the Z-axis positive side. In the acoustic wave device 1A, the plan view (transparent view) of the main surface 10a of the substrate 10 as viewed from the Z-axis positive side is the same or substantially the same as the second plan view in FIG. 2B, and the plan view of the main surface 10b of the substrate 10 as viewed from the Z-axis positive side is the same or substantially the same as the third plan view in FIG. 2C. FIG. 7 is a cross-sectional view taken along line VII-VII in FIG. 8.

As illustrated in FIGS. 7 and 8, the acoustic wave device 1A includes the substrates 10 and 20, the metal films 31, 32, and 33, the functional electrodes 34, the via conductors 11, the insulation films 13 and 23, the planar electrodes 12, and the bump electrodes 40. The acoustic wave device 1A according to the present modification differs from the acoustic wave device 1 in the locations of the via conductors 11 and the metal films 31, 32, and 33. The components of the acoustic wave device 1A according to the present modification that are the same or substantially the same as those of the acoustic wave device 1 according to the above-described example embodiment will not be described below with a focus on different components.

The metal films 31 are examples of the first metal film and, as illustrated in FIG. 7, are planar electrodes, in contact with the via conductors 11, that are disposed on the main surface 10a. The metal film 31 is, for example, a multilayer body including a plurality of metal layers.

The metal film 32 is an example of the second metal film and, as illustrated in FIG. 7, is a planar electrode in contact with the metal film 31. The metal films 32 are, for example, multilayer bodies including a plurality of metal layers.

The metal films 33 are examples of the third metal film and, as illustrated in FIGS. 7 and 8, are planar electrodes that are disposed on the main surface 20a, connected to the functional electrodes 34, and in contact with the metal films 32. The metal film 33 is, for example, a multilayer body including a plurality of metal layers.

The functional electrodes 34 are disposed on the main surface 20a and perform electromechanical transduction together with the substrate 20.

As illustrated in FIG. 7, the metal films 31, 32, and 33 define the support portion and are laminated together in this order between the main surface 10a and the main surface 20a so as to provide a space between the main surface 10a and the main surface 20a.

In FIG. 7, the right via conductor 11 of the two via conductors 11 does not overlap the functional electrode 34 in plan view of the main surfaces 10a and 20a.

An acoustic wave device according to modification 6 of an example embodiment of the present invention differs from the acoustic wave device 1 according to the above-described example embodiment only in the multilayer structure of the metal films that define the support portion. Accordingly, the components of the acoustic wave device according to modification 6 that are the same or substantially the same as those of the acoustic wave device 1 according to the above-described example embodiment will not be described below with a focus on the components that differ from those of the acoustic wave device 1 according to the above-described example embodiment.

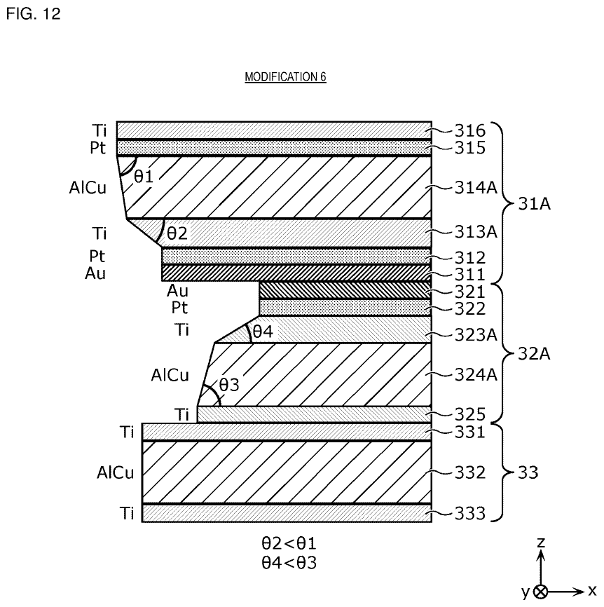

FIG. 12 is a cross-sectional view illustrating a multilayer structure of metal films 31A to 33A of an acoustic wave device according to modification 6. FIG. 12 is a cross-sectional view schematically illustrating region V in FIG. 4 in an enlarged manner.

As illustrated in FIG. 12, the support portion includes the metal film 31A disposed on the main surface 10a, the metal film 33A disposed on the main surface 20a, and the metal film 32A disposed between the metal films 31A and 33A.

The metal film 31A includes the intermediate layer 316, the intermediate layer 315, a main electrode layer 314A, an intermediate layer 313A, the intermediate layer 312, and the joint layer 311 in order from the main surface 10a side.

The intermediate layer 313A and the intermediate layer 316 are metal layers including, for example, titanium (Ti) as a main component and define and function as the first diffusion barrier layer.

The intermediate layer 312 and the intermediate layer 315 are metal layers including, for example, platinum (Pt) as a main component and define and function as diffusion barrier layers together with the intermediate layers 313A and 316.

The main electrode layer 314A is an example of the first main electrode layer, is a metal layer including, for example, aluminum (Al) and copper (Cu) as main components, and defines and functions as a main medium through which a high-frequency signal is transmitted in the metal film 31A.

The joint layer 311 is an example of the first joint layer, is a metal layer including, for example, gold (Au) as a main component, and has the function of providing good electrical and mechanical joint with the metal film 32A.

The intermediate layers 312 and 315 may be omitted in the metal film 31A according to the present modification.

In addition, as illustrated in FIG. 12, the metal film 32A includes the joint layer 321, the intermediate layer 322, an intermediate layer 323A, a main electrode layer 324A, and the intermediate layer 325 in order from the main surface 10a side.

The joint layer 321 is an example of the second joint layer, is a metal layer including, for example, gold (Au) as a main component, and has the function of providing good electrical and mechanical joint with the metal film 31A.

The intermediate layer 322 is a metal layer including, for example, platinum (Pt) as a main component and defines and functions as the second diffusion barrier layer together with the intermediate layer 323A.

The intermediate layer 323A (second intermediate layer) and the intermediate layer 325 are metal layers including, for example, titanium (Ti) as a main component and define and function as diffusion barrier layers.

The main electrode layer 324A is an example of the second main electrode layer, is a metal layer including, for example, aluminum (Al) and copper (Cu) as main components, and defines and functions as a main medium through which a high-frequency signal is transmitted in the metal film 32A.

The intermediate layer 322 may be omitted in the metal film 32A according to the modification.

In addition, as illustrated in FIG. 12, the metal film 33 includes the intermediate layer 331, the main electrode layer 332, and an intermediate layer 333 in order from the main surface 10a side.

The intermediate layers 331 and 333 are metal layers including, for example, titanium (Ti) as a main component and define and function as diffusion barrier layers.

The main electrode layer 332 is a metal layer including, for example, aluminum (Al) and copper (Cu) as main components and defines and functions as a main medium through which a high-frequency signal is transmitted in the metal film 33.

The intermediate layers 331 and 333 may be omitted from the metal film 33A according to the present modification, and the metal film 33A may include only the main electrode layer 332.

In the metal film 31A, angle θ2 between the side surface of the intermediate layer 313A and the first plane parallel to the main surface 10a is smaller than angle θ1 between the side surface of the main electrode layer 314A and the first plane.

As a result, since the exposed area of the side surface of the intermediate layer 313A increases, it is possible to reduce or prevent the alloying (electrochemical migration) of the metal component of the joint layer 311 and the metal component of the main electrode layer 314A due to connection of these metal components through the side surface of the intermediate layer 313A.

A portion of the side surface of the main electrode layer 314A is preferably covered with the intermediate layer 313A. As a result, it is possible to further reduce or prevent the alloying (electrochemical migration) of the metal component of the joint layer 311 and the metal component of the main electrode layer 314A due to connection of these metal components. A portion of the side surface of the main electrode layer 314A is preferably covered with the intermediate layer 313A, and the other portion of the main electrode layer 314A is preferably exposed without being covered with the intermediate layer 313A. As a result, it is possible to reduce or prevent the main electrode layer 314A from being cracked and broken due to joint stress between the main electrode layer 314A and the intermediate layer 313A.

In addition, the area of the joint interface between the main electrode layer 314A and the intermediate layer 313A is larger than the area of the joint interface between the joint layer 321 and the intermediate layer 313A.

In the metal film 32A, angle θ4 between the side surface of the intermediate layer 323A and the first plane is smaller than angle θ3 between the side surface of the main electrode layer 324A and the first plane.

As a result, since the exposed area of the side surface of the intermediate layer 323A increases, it is possible to reduce or prevent the alloying (electrochemical migration) of the metal component of the joint layer 321 and the metal component of the main electrode layer 324A due to connection of these metal components through the side surface of the intermediate layer 323A.

A portion of the side surface of the main electrode layer 324A is preferably covered with the intermediate layer 323A. As a result, it is possible to further reduce or prevent the alloying (electrochemical migration) of the metal component of the joint layer 321 and the metal component of the main electrode layer 324A due to connection of these metal components. A portion of the side surface of the main electrode layer 324A is preferably covered with the intermediate layer 323A, and the other portion of the main electrode layer 324A is preferably exposed without being covered with the intermediate layer 323A. As a result, it is possible to reduce or prevent the main electrode layer 324A from being cracked and broken due to joint stress between the main electrode layer 324A and the intermediate layer 323A.

In addition, the area of the joint interface between the main electrode layer 324A and the intermediate layer 323A is larger than the area of the joint interface between the joint layer 321 and the intermediate layer 323A.

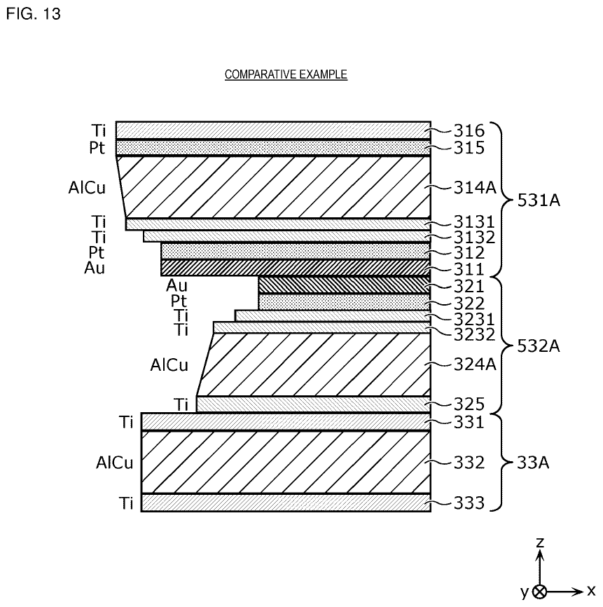

FIG. 13 is a cross-sectional view illustrating a multilayer structure of metal films 531A and 532A and the metal film 33A of an acoustic wave device according to a comparative example. The acoustic wave device according to the comparative example differs from the acoustic wave device according to modification 6 only in that the metal films 531A and 532A are provided instead of the metal films 31A and 32A.

The metal film 531A includes the intermediate layer 316, the intermediate layer 315, the main electrode layer 314A, intermediate layers 3131 and 3132, the intermediate layer 312, and the joint layer 311 in order from the main surface 10a side.

The intermediate layers and 3132 and the 3131 intermediate layer 316 are metal layers including, for example, titanium (Ti) as a main component.

In addition, as illustrated in FIG. 13, the metal film 532A includes the joint layer 321, the intermediate layer 322, intermediate layers 3231 and 3232, the main electrode layer 324A, and the intermediate layer 325 in order from the main surface 10a side.

The intermediate layers 3231 and 3232 and the intermediate layer 325 are metal layers including, for example, titanium (Ti) as a main component.

In the metal film 531A, the intermediate layers 3131 and 3132 as diffusion barrier films are formed in two stages to reduce or prevent alloying (electrochemical migration) of the metal component of the joint layer 311 and the metal component of the main electrode layer 314A. The alloying (electrochemical migration) of the metal component of the joint layer 311 and the metal component of the main electrode layer 314A is reduced or prevented by making the film area of the intermediate layer 3132 smaller than the film area of the intermediate layer 3131 to form a step between the side surfaces of the intermediate layers 3131 and 3132.

Similarly, in the metal film 532A, the intermediate layers 3231 and 3232 as diffusion barrier films are formed in two stages to reduce or prevent the alloying (electrochemical migration) of the metal component of the joint layer 321 and the metal component of the main electrode layer 324A. The alloying (electrochemical migration) of the metal component of the joint layer 321 and the metal component of the main electrode layer 324A is reduced or prevented by making the film area of the intermediate layer 3231 smaller than the film area of the intermediate layer 3232 to form a step between the side surfaces of the intermediate layers 3231 and 3232. However, in the acoustic wave device according to the comparative example, the intermediate layers 3131 and 3132 need to be formed by different film formation processes, and the intermediate layers 3231 and 3232 need to be formed by different film formation processes, and accordingly, the manufacturing process becomes complicated.

In contrast, in the acoustic wave device according to modification 6, the intermediate layer 313A can be formed in a single film formation process, and the intermediate layer 323A can be formed in a single film formation process, and accordingly, the manufacturing process can be simplified.

In the acoustic wave device according to modification 6, the metal films 31A and 32A do not need to have angles θ2 and 04, respectively, and at least one of the metal films 31A and 32A only needs to have the angles θ2 or 04.

As described above, the acoustic wave device 1 according to the above-described example embodiment includes the substrate 10 including the main surfaces 10a and 10b that face away from each other, the substrate 20 including the main surface 20a that faces the main surface 10a, the functional electrode 34 disposed on the main surface 20a, the support portion disposed between the main surface 10a and the main surface 20a so as to provide a space between the main surface 10a and the main surface 20a, and the via conductor 11, disposed in the substrate 10, that extends from the main surface 10a toward the main surface 10b, the support portion includes the metal film 31, in contact with the via conductor 11, that is disposed on the main surface 10a and the metal film 32, in contact with the metal film 31, that is disposed on the opposite side of the via conductor 11 with the metal film 31 therebetween, and, in plan view of the main surface 10a, the region of the metal film 31 includes the region of the metal film 32, and the area of the metal film 31 is larger than the area of the metal film 32, and the hardness of the metal film 32 is higher than the hardness of the metal film 31.

As a result, the metal film 32 with a smaller area can be reduced or prevented from being crushed during pressure joining of the metal films 31 and 32, and a joint that wraps the metal film 32 with a smaller area with the metal film 31 with a larger area can be performed. Accordingly, it is possible to provide the acoustic wave device 1 that can reduce or prevent local heating and generation of unnecessary grains at the end portion of the joint interface and includes the support portions with improved joint strength.

In addition, for example, in the acoustic wave device 1, the support portion further includes the metal film 33 that is disposed on the main surface 20a, connected to the functional electrode 34, and in contact with the metal film 32, and the hardness of the metal film 33 is higher than the hardness of the metal film 31.

As a result, a joint configuration that wraps the metal films 32 and 33 with the metal film 31 can be achieved. Accordingly, it is possible to provide the acoustic wave device 1 that can reduce or prevent local heating and generation of unnecessary grains at the end portion of the joint interface and includes the support portions with improved joint strength.

In addition, for example, in the acoustic wave device 1, the metal film 31 includes the main electrode layer 314, the intermediate layer 313, and the joint layer 311 in order from the main surface 10a side, and the metal film 32 includes the joint layer 321, the intermediate layer 323, and the main electrode layer 324 in order from the main surface 10a side.

As a result, since each of the metal films 31 and 32 includes a plurality of metal layers having different functions, good joining of the metal films 31 and 32 can be achieved.

In addition, for example, in the acoustic wave device according to modification 6, angle θ2 between the side surface of the intermediate layer 313A and the first plane parallel to the main surface 10a is smaller than angle θ1 between the side surface of the main electrode layer 314A and the first plane.

As a result, since the exposed area of the side surface of the intermediate layer 313A increases, it is possible to reduce or prevent the alloying (electrochemical migration) of the metal component of the joint layer 311 and the metal component of the main electrode layer 314A due to connection of these metal components through the side surface of the intermediate layer 313A.

In addition, for example, in the acoustic wave device according to modification 6, a portion of the side surface of the main electrode layer 314A is covered with the intermediate layer 313A.

As a result, it is possible to further reduce or prevent the alloying (electrochemical migration) of the metal component of the joint layer 311 and the metal component of the main electrode layer 314A due to connection of these metal components.

In addition, for example, in the acoustic wave device according to modification 6, the area of the joint interface between the main electrode layer 314A and the intermediate layer 313A is larger than the area of the joint interface between the joint layer 311 and the intermediate layer 313A.

In addition, for example, in the acoustic wave device according to modification 6, the intermediate layer 313A includes titanium, for example.

In addition, for example, in the acoustic wave device according to modification 6, angle θ4 between the side surface of the intermediate layer 323A and the first plane is smaller than angle θ3 between the side surface of the main electrode layer 324A and the first plane.

As a result, since the exposed area of the side surface of the intermediate layer 323A increases, it is possible to reduce or prevent the alloying (electrochemical migration) of the metal component of the joint layer 321 and the metal component of the main electrode layer 324A due to connection of these metal components through the side surface of the intermediate layer 323A.

In addition, for example, in the acoustic wave device according to modification 6, a portion of the side surface of the main electrode layer 324A is covered with the intermediate layer 323A.

As a result, it is possible to further reduce or prevent the alloying (electrochemical migration) of the metal component of the joint layer 321 and the metal component of the main electrode layer 324A due to connection of these metal components.

In addition, for example, in the acoustic wave device according to modification 6, the area of the joint interface between the main electrode layer 324A and the intermediate layer 323A is larger than the area of the joint interface between the joint layer 321 and the intermediate layer 323A.

In addition, for example, in the acoustic wave device according to modification 6, the intermediate layer 323A includes titanium, for example.

In addition, for example, in the acoustic wave device 1, the element with the highest weight ratio of the metal elements of the joint layer 321 is the same or substantially the same as the element with the highest weight ratio of the metal elements of the joint layer 311.

As a result, since the joint strength of the metal film 32 and the metal film 33 can be improved, the strength of the support portion can be improved.

In addition, for example, in the acoustic wave device 1, in plan view of the main surface 10a, the region of the metal film 31 includes the region of the metal film 32, the region of the intermediate layer 323 includes the region of the joint layer 321, the area of the intermediate layer 323 is larger than the area of the joint layer 321, the region of the main electrode layer 324 includes the region of the intermediate layer 323, the area of the main electrode layer 324 is larger than the area of the intermediate layer 323, the linear expansion coefficient of the joint layer 321 is larger than the linear expansion coefficient of the intermediate layer 323, and the linear expansion coefficient of the main electrode layer 324 is larger than the linear expansion coefficient of the joint layer 321.

As a result, when the metal film 31 and the metal film 32 are heated during pressure joining, since the main electrode layer 324 with a relatively large linear expansion coefficient has a larger area than the intermediate layer 323 and the joint layer 321, the main electrode layer 324 and the intermediate layer 323 have a bimetal structure at the end portions of the main electrode layer 324 and the intermediate layer 323. Accordingly, since the main electrode layer 324 and the intermediate layer 323 are likely to expand toward the joint layer 321 at the end portions, and both ends of the main electrode layer 324 are pushed up toward the metal film 31, a good joint can be obtained at the joint end of the metal film 32.

In addition, for example, in the acoustic wave device 1, the substrate 20 has piezoelectricity, the IDT electrode 54 is disposed on the main surface 20a, the IDT electrode 54 includes the plurality of electrode fingers 61a and the plurality of electrode fingers 61b that are disposed in parallel to each other, the busbar electrode 62a that connects one ends of the plurality of electrode fingers 61a to each other, and the busbar electrode 62b, disposed to face the busbar electrode 62a with the plurality of electrode fingers 61a and the plurality of electrode fingers 61b therebetween, that connects one ends of the plurality of electrode fingers 61b to each other, and the functional electrode 34 includes the plurality of electrode fingers 61a and the plurality of electrode fingers 61b.

As a result, a surface acoustic wave device or an XBAR device including the support portion with improved joint strength can be provided.

In addition, for example, in the acoustic wave device 1, the substrate 20 includes the piezoelectric film 53 including the main surface 20a and the support substrate 51, and d/p is, for example, about 0.5 or less where d is the thickness of the piezoelectric film 53 and p is the electrode finger pitch of the IDT electrode 54.

As a result, an XBAR device including the support portion with improved joint strength can be provided.

In addition, for example, in the acoustic wave device 1, the support portion further includes the metal film 33 that is disposed on the main surface 20a, connected to the functional electrode 34, and in contact with the metal film 32, the metal film 33 includes the busbar electrodes 62a and 62b, and the hardness of the metal film 33 is greater than the hardness of the metal film 31.

As a result, a joint that wraps the metal films 32 and 33 with the metal film 31 can be achieved. Accordingly, it is possible to provide the acoustic wave device 1 that can reduce or prevent local heating and generation of unnecessary grains at the end portion of the joint interface and includes the support portions with improved joint strength.

In addition, for example, in the acoustic wave device 1, the functional electrode 34 includes the lower electrode 66, the piezoelectric layer 67, and the upper electrode 68 in order from the main surface 20a.

As a result, a bulk acoustic wave device including the support portion with improved joint strength can be provided.

In addition, for example, in the acoustic wave device 1, the substrate 10 includes silicon.

As a result, the machining accuracy of the substrate 10 is improved.

In addition, for example, in the acoustic wave device 1, in plan view of the main surface 10a, the region of the metal film 31 includes the region of the via conductor 11 and the area of the metal film 31 is larger than the area of the via conductor 11, and the region of the metal film 32 includes the region of the via conductor 11 and the area of the metal film 32 is larger than the area of the via conductor 11.

As a result, the substrate 10 adjacent to the via conductor 11 in the X-axis direction is joined to the metal film 31, and the substrate 10 joined to the metal film 31 can absorb the compressive stress of the metal films 31 and 32, and accordingly, the via conductor 11 can be reduced or prevented from deforming and peeling off.

In addition, for example, in the acoustic wave device 1, in plan view of the main surface 20a, the region of the metal film 33 includes the region of the metal film 32, and the area of the metal film 33 is larger than the area of the metal film 32.

As a result, since the metal film 32 does not restrict the positional regions of the functional electrode 34 and the metal film 33 on the main surface 20a, the positional layout of the functional electrode 34 and the metal film 33 can be prioritized.

Acoustic wave devices according to the present invention have been described by using example embodiments, but the present invention is not limited to the example embodiments described above. Modifications obtained by applying changes conceived by those skilled in the art without deviating from the scope and gist of the present invention and various devices incorporating the acoustic wave device according to example embodiments of the present invention are also included in the present invention.

Example embodiments of the present invention are widely applicable as a compact acoustic wave device to communication devices, such as cellular phones, for example.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a first substrate including a first main surface and a second main surface facing away from each other;
a second substrate including a third main surface facing the first main surface;
a functional electrode on the third main surface;
a support portion between the first main surface and the third main surface and providing a space between the first main surface and the third main surface; and
a via conductor located in the first substrate and extending from the first main surface toward the second main surface; wherein
the support portion includes:
a first metal film in contact with the via conductor and provided on the first main surface; and
a second metal film in contact with the first metal film and provided on an opposite side of the via conductor with the first metal film therebetween;
in plan view of the first main surface, a region of the first metal film includes a region of the second metal film, and an area of the first metal film is larger than an area of the second metal film; and
a hardness of the second metal film is greater than a hardness of the first metal film.

2. The acoustic wave device according to claim 1, wherein
the support portion further includes a third metal film on the third main surface, connected to the functional electrode, and in contact with the second metal film; and
a hardness of the third metal film is greater than the hardness of the first metal film.

3. The acoustic wave device according to claim 1, wherein
the first metal film includes a first main electrode layer, a first diffusion barrier layer, and a first joint layer in order from a first main surface side;
the second metal film includes a second joint layer, a second diffusion barrier layer, and a second main electrode layer in order from the first main surface side; and
the first joint layer and the second joint layer are joined to each other.

4. The acoustic wave device according to claim 3, wherein an angle between a side surface of the first diffusion barrier layer and a first plane parallel to the first main surface is smaller than an angle between a side surface of the first main electrode layer and the first plane.

5. The acoustic wave device according to claim 4, wherein a portion of the side surface of the first main electrode layer is covered with the first diffusion barrier layer.

6. The acoustic wave device according to claim 4, wherein an area of a joint interface between the first main electrode layer and the first diffusion barrier layer is larger than an area of a joint interface between the first joint layer and the first diffusion barrier layer.

7. The acoustic wave device according to claim 4, wherein the first diffusion barrier layer includes titanium.

8. The acoustic wave device according to claim 3, wherein an angle between a side surface of the second diffusion barrier layer and a first plane parallel to the first main surface is smaller than an angle between a side surface of the second main electrode layer and the first plane.

9. The acoustic wave device according to claim 8, wherein a portion of the side surface of the second main electrode layer is covered with the second diffusion barrier layer.

10. The acoustic wave device according to claim 8, wherein an area of a joint interface between the second main electrode layer and the second diffusion barrier layer is larger than an area of a joint interface between the second joint layer and the second diffusion barrier layer.

11. The acoustic wave device according to claim 8, wherein the second diffusion barrier layer includes titanium.

12. The acoustic wave device according to claim 3, wherein an element with a highest weight ratio of metal elements of the second joint layer is the same as an element with a highest weight ratio of metal elements of the first joint layer.

13. The acoustic wave device according to claim 3, wherein
in plan view of the first main surface:
a region of the first metal film includes a region of the second metal film;
a region of the second diffusion barrier layer includes a region of the second joint layer, and an area of the second diffusion barrier layer is larger than an area of the second joint layer;
a region of the second main electrode layer includes the region of the second diffusion barrier layer, and an area of the second main electrode layer is larger than the area of the second diffusion barrier layer;
a linear expansion coefficient of the second joint layer is greater than a linear expansion coefficient of the second diffusion barrier layer; and
a linear expansion coefficient of the second main electrode layer is greater than the linear expansion coefficient of the second joint layer.

14. The acoustic wave device according to claim 1, wherein
the second substrate has piezoelectricity;
an interdigital transducer (IDT) electrode is provided on the third main surface;
the IDT electrode includes a plurality of first electrode fingers and a plurality of second electrode fingers in parallel to each other;
a first busbar electrode connects ends of the plurality of first electrode fingers to each other; and
a second busbar electrode that connects ends of the plurality of second electrode fingers to each other and faces the first busbar electrode with the plurality of first electrode fingers and the plurality of second electrode fingers therebetween; and
the functional electrode includes the plurality of first electrode fingers and the plurality of second electrode fingers.

15. The acoustic wave device according to claim 14, wherein
the second substrate includes a support substrate and a piezoelectric film including the third main surface; and
d/p is about 0.5 or less, where d is a thickness of the piezoelectric film, and p is an electrode finger pitch of the IDT electrode.

16. The acoustic wave device according to claim 14, wherein
the support portion further includes a third metal film on the third main surface, connected to the functional electrode, and in contact with the second metal film;
the third metal film includes the first busbar electrode and the second busbar electrode; and
a hardness of the third metal film is greater than a hardness of the first metal film.

17. The acoustic wave device according to claim 1, wherein the functional electrode includes a first planar electrode, a piezoelectric thin film, and a second planar electrode in order from the third main surface.

18. The acoustic wave device according to claim 1, wherein the first substrate includes silicon.

19. The acoustic wave device according to claim 1, wherein
in plan view of the first main surface:
the region of the first metal film includes a region of the via conductor, and the area of the first metal film is larger than an area of the via conductor; and
the region of the second metal film includes the region of the via conductor, and the area of the second metal film is larger than the area of the via conductor.

20. The acoustic wave device according to claim 2, wherein, in plan view of the third main surface, a region of the third metal film includes the region of the second metal film, and an area of the third metal film is larger than the area of the second metal film.
